(19) United States
(12) Patent Application Publication
(10) Pub. No.: US 2015/0193205 A1
(43) Pub. Date: Jul. 9, 2015

(54) Method for generating an output of a random source of a random generator

(71) Applicant: Robert Bosch GmbH, Stuttgart (DE)

(72) Inventor: Eberhard BOEHL, Reutlingen (DE)

(21) Appl. No.: 14/589,345

(22) Filed: Jan. 5, 2015

(30) Foreign Application Priority Data
Jan. 9, 2014 (DE) 10 2014 200 164.1

(51) Int. Cl. G06F 7/58; H03M 7/30

(52) U.S. Cl. CPC G06F 7/58; H03M 7/30

(57) ABSTRACT

In a method for generating an output of a random source, the random source is sampled using at least two sampling units in such a way that an output signal is generated in each case, and the output signals of each sampling unit are each processed by a processing unit.

### BACKGROUND OF THE INVENTION

1. Field of the Invention

The present invention relates to a method for generating an output of a random source of a random generator and a configuration for carrying out the method.

2. Description Of The Related Art

Random numbers as the results or outputs of random sources in random generators are required for many applications. Random generators are methods which supply a sequence of random numbers. A decisive criterion of the quality of random numbers is whether the result of the generation may be considered to be independent of earlier results.

Random numbers are required, for example, for cryptographic methods, these methods being used to generate keys for these encryption methods. Thus, random generators or random number generators (RNG) are used to generate master keys for symmetrical encryption methods and protocol handshaking in ECC (elliptical curve cryptography), which prevent a power analysis attack and attacks by recording (replay attacks).

There are two fundamental types of random generators, specifically, on the one hand, pseudo random number generators (PRNG) for high throughputs and low security levels. A secret value is typically input into a PRNG and each input value will always result in the same output series. A good PRNG, however, will output a number series which appears random and which will pass most tests.

It is to be noted that high requirements with regard to the random properties are placed on keys for cryptographic methods. Therefore, pseudo random number generators (PRNG), represented, for example, by an LFRS (linear feedback shift register) are not suitable for this purpose. Only a generator of true random numbers, which is referred to as a true random number generator (TRNG) fulfills the stated demands. This represents another type of a random generator. In this case, natural noise processes are utilized to obtain a nonpredictable result.

Noise generators which utilize the thermal noise of resistors or semiconductors or the shot noise at potential barriers, for example, at pn junctions, are typical. A further possibility is the utilization of the radioactive decomposition of isotópes.

While the “classical” methods use analog elements, for example, resistors, as noise sources, in the more recent past, digital elements, for example, inverters, have been used. These have the advantage of a lower complexity in the circuit outlay, because they are provided as standard elements. Furthermore, such circuits may also be used in freely programmable circuits, for example, FPGAs.

Thus, for example, the use of ring oscillators is known, which represent an electronic oscillator circuit. An odd number of inverters is interconnected to form a ring therein, whereby an oscillation at a natural frequency arises. The natural frequency is dependent on the number of the inverters in the ring, the properties of the inverters, the conditions of the interconnection, specifically the line capacitances, the operating voltage, and the temperature. Due to the noise of the inverters, a random phase shift arises in relation to the ideal oscillator frequency, which is used as a random process for the TRNG. It is to be noted that ring oscillators oscillate independently and do not require external components, for example, capacitors or coils.

The output of the ring oscillators may be compressed or subjected to post-processing to compact or bundle, i.e., increase, the entropy and eliminate any tendency (bias).

One problem in this context is that the ring oscillator must be sampled as close as possible to an expected ideal flank so that a random sampled value is obtained. A possibility for this purpose is shown in the publication by Bock, H., Bucci, M., Luzzi, R.: An Offset-compensated Oscillator-based Random Bit Source for Security Applications, CHES 2005, of how the sampling always takes place in the vicinity of an oscillator flank due to the regulated shifting of the sampling time.

A method for generating random numbers with the aid of a ring oscillator is known from the European patent publication EP 1 686 458 B1, in which a first and a second signal are provided, the first signal being sampled in a way triggered by the second signal. In the described method, a ring oscillator is sampled multiple times, noninverting delays, specifically an even number of inverters as delay elements, always being used. The oscillator ring, beginning from a starting point, is always sampled simultaneously or with mutual delay after an even number of inverters. The shift of the sampling time may thus be omitted; instead the multiple sample signals are analyzed.

In the publication “Design of Testable Random Bit Generators” by Bucci, M. and Luzzi, R., CHES 2005, a method is provided, using which an influence of the random source may be established. Attacks may thus be avoided. A direct differentiation between random values and deterministic values is not possible thereby, however. It is possible to evaluate the quality of the random source by counting the transitions.

A further possibility is provided by the use of multiple ring oscillators. This is described, for example, in the publication by Sunar B. et al.: Approvable Secure True Random Number Generator with Built In Tolerance Attacks, IEEE Trans. On Computers, 1/2007. Sampled values of multiple ring oscillators are linked to one another and analyzed.

As already stated, an odd number of inverters are interconnected to form a ring in ring oscillators, whereby oscillation arises at a natural frequency. The natural frequency is dependent on the number of the inverters in the ring, the properties of the inverters, the conditions of the interconnection, i.e., the line capacitances, the operating voltage, and the temperature. Due to the noise of the inverters, a random phase shift results in relation to the ideal oscillator frequency, which is used as the random process for the TRNG.

An advantageous implementation of a TRNG source with the aid of a ring oscillator sampled at multiple points is shown in FIG. 1. This circuit also offers the advantage that a correlation with the system clock may be established and errors may be discovered if special implementation conditions having a uniform capacitive load of all nodes of the ring oscillator are provided and the switch elements used, for example, flip-flops, inverters, are designed so that they react as uniformly as possible to rising and falling flanks.

A possibility is described in the published German patent application document DE 60 2004 011 081 T2 of how a TRNG source may be tested after “post-processing,” and how this post-processing is offset in a certification mode for this purpose.

### BRIEF SUMMARY OF THE INVENTION

A method is therefore provided, which is built in one embodiment on a compression method for post-processing an output of a random source of a random generator. In the case of this fundamental compression method, the random source outputs a digital output signal having a bit width of at least one bit, the output signal being compressed. In the scope of the compression, a block-by-block linear linkage of n successive bits of the output signal is carried out, n being a compression factor, whereby a compressed output signal is generated which includes a sequence of compressed signal values. The sequence of the compressed signal values may be checked with regard to its distribution.

In this compression method, it may be provided in one embodiment that the bits of the output signal are either directly linked to one another by a linear operation and this combined signal is serially compressed by a linear operation, or initially compression is carried out bit-by-bit and the compressed values are subsequently subjected to further processing, for example, linked linearly. A first post-processing step and a second post-processing step may be provided, a linear linkage, for example, using an XOR element or an XNOR element, being carried out in at least one of the two.

All previous methods having exclusively digital elements as the entropy source, for example, an odd number of inverters connected to form a ring, sometimes require very complex post-processing circuits, which enrich the entropy, on the one hand, and ensure a uniform distribution of the random bits between the values 0 and 1, on the other hand. The provided compression method offers a simple possibility for post-processing. In particular, the complex post-processing having a certification mode as described in the published German patent application document DE 60 2004 011 081 T2 may be omitted.

According to the provided compression method, a TRNG source having multiple outputs may be used, each of these outputs being equipped with a simple compression function, for example, a serial XOR. The outlay of such a method is sufficiently low that a TRNG having approximately 200 gate equivalents may be implemented. This is significantly more advantageous than known methods.

Block-by-block linear linkage may be achieved, for example, by a serial XOR, for example, the output signal being linearly linked by XOR to an intermediate signal. A linkage using XNOR is also possible. The result of this linkage is stored in a storage element, for example, a flip-flop. The output signal of this storage element is the intermediate signal. The compressed signal formed in the storage element in this way is read out after a predefined number n of cycles. The storage element is subsequently reset. Number n should be odd as much as possible, because n zeros and n ones then provide different results.

The check of the distribution may be carried out, for example, by counting the occurrence of bit value 0 and bit value 1 in separate counters for m compressed output bits and carrying out the comparison by calculating the difference of these counter values and by comparing the difference to a predefined barrier.

If a ring oscillator is used as the random source, its frequency may be influenced by selecting the number of inverting elements or also by changing the operating conditions, for example, operating voltage, temperature, etc. The number of the inverting elements in the ring oscillator may be changed as follows:

a) generic approach in the case of the synthesis using a variable number of inverting elements. However, this may only be carried out in an FPGA after a further synthesis.

b) structure of the ring oscillator provided with inverting elements, which may be partially bypassed, controlled by a control signal. This auxiliary circuit amplifies the unequal capacitances of the nodes in the ring oscillator. However, this does not have a disadvantageous effect if the compression factor and/or the sampling frequency is/are varied accordingly.

Changes of the operating conditions may be carried out as follows:

a) by a separately controllable supply voltage, which is explicitly led out, or by series resistors in the supply of the ring oscillator (voltage drop),

b) by heating or cooling elements, which are optionally switched in.

A mutual comparison of the number of zeros and ones means, for example, that the greatest and smallest number of an assignment may be established by greater/lesser comparison, for example,

a) in that it is checked whether a difference is negative or

b) in that the counter values are compared bit-by-bit beginning from the MSB; at the first deviation at a bit position, the value with a 1 at this point is greater than the other, and then the difference of greatest and smallest value is calculated, which is in turn compared to a fixed barrier.

A compression method is therefore used, in the case of which the uniform distribution between 0 and 1 is achieved by a simple compression with the aid of XOR-linkage. The unequal distribution referred to as “bias” is achieved by an appropriate degree of compression in conjunction with a suitable selection of the sampling frequency.

With the aid of a suitable testing method, it may be established whether the bias is sufficiently small or, for example, because of a correlation of the oscillator to an internal or external clock, a sufficiently high random value is not achievable.

The above-explained compression method has the disadvantage that the achievable bit rate of the TRNG is lower than would be possible according to the available entropy. This is caused because the bias is remedied by high compression using the simple XOR compression, but this high compression cancels out entropy, on the other hand. This is described in the publication of Markus Dichtl (Siemens AG): “Bad and Good Ways of Post-Processing Biased Physical Random Numbers”: see Biryukov, A. (ed.) FSE 2007, LNCS, volume 4593, pp 127-152, Springer, Heidelberg 2007. It has been typical up to this point to use multiple ring oscillators to increase the entropy and therefore the possible bit rate of the TRNG.

Additional sampling elements, for example, flip-flops, may now be used on the same random source, for example, on the same ring oscillator.

The sampling elements may use the same sampling points as the ring oscillator or other sampling points. The sampling may be carried out using the same or a different sampling frequency. Since only one ring oscillator is required, hardware outlay and power consumption are lower than in the related art.

Furthermore, it is to be noted that further samples mean a capacitive load and a lower frequency may thus result in the case of a ring oscillator. This may be compensated for by a lower number of inverting elements.

Further advantages and embodiments of the present invention result from the description and the appended drawings.

It is obvious that the above-mentioned features and the features to be explained hereafter are usable not only in the particular specified combination, but rather also in other combinations or alone, without leaving the scope of the present invention.

### BRIEF DESCRIPTION OF THE DRAWINGS

FIG. 1 shows an embodiment of a ring oscillator.

FIG. 2 shows a configuration for compressing an output of a ring oscillator together with the ring oscillator from FIG. 1.

FIG. 3 shows another configuration for compression.

FIG. 4 shows an embodiment of the configuration for carrying out the provided method.

FIG. 5 shows another embodiment of the configuration for carrying out the provided method.

FIG. 6 shows a very simplified view of an embodiment of a circuit configuration.

### DETAILED DESCRIPTION OF THE INVENTION

The present invention is schematically shown in the drawings on the basis of specific embodiments and will be described in detail hereafter with reference to the drawings.

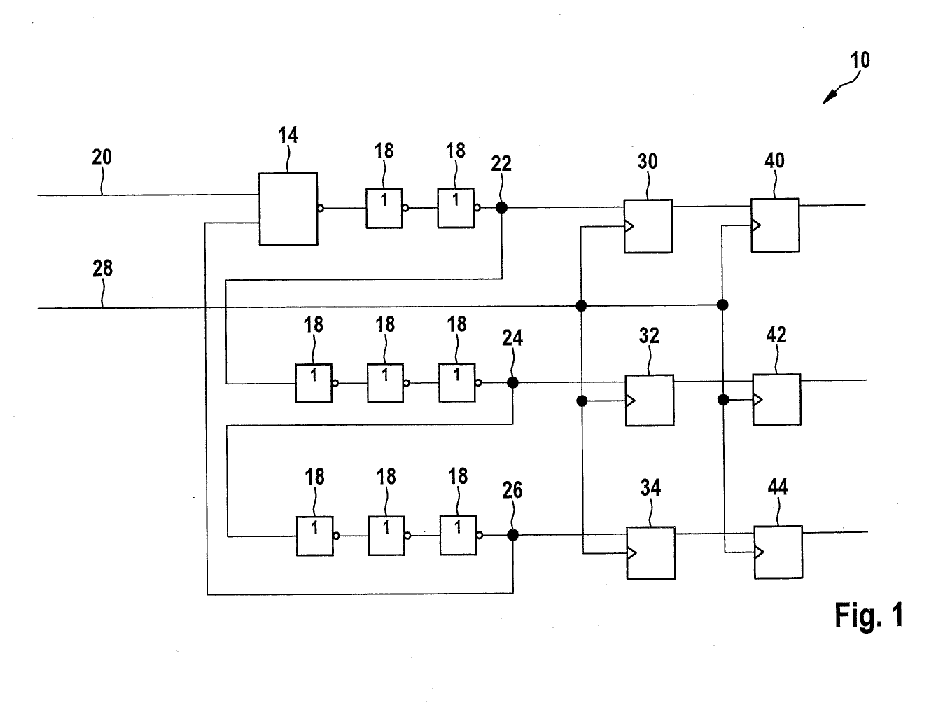

FIG. 1 shows an embodiment of a ring oscillator as a random source, which is identified as a whole with reference number 10. Ring oscillator 10 has a NAND element 14 and eight inverters 18 and therefore nine inverting elements. Ring oscillator 10 therefore has an odd number of inverting elements and three taps or sampling points.

Ring oscillator 10 may be started and stopped using a first input 20. The sampling rate is specified via a second input 28. Furthermore, the illustration shows a first sampling point 22, a second sampling point 24, and a third sampling point 26. This means that beginning from first sampling point 22, sampling is always carried out after an odd number of inverting elements. However, this is not necessarily required for the provided method.

First sampling point 22 is sampled using a first flip-flop 30;

sampled value s10 results. Second sampling point 24 is sampled using a second flip-flop 32; sampled value s11 results. Third sampling point 26 is sampled using a third flip-flop 34; sampled value s12 results. A further fourth flip-flop 40 is associated with first flip-flop 30. It fulfills a storage function and outputs value s10′, which chronologically follows value s10, i.e., s10 and s10′ are chronologically successive sampled values of first sampling point 22. Correspondingly, a fifth flip-flop 42, which outputs s11′, is associated with second flip-flop 32, and a sixth flip-flop 44, which outputs s12′, is associated with third flip-flop 34. Flip-flops 40, 42, and 44 are suitable for the purpose of triggering metastable states of flip-flops 30, 32, and 34. Metastable states arise because switching over of the signal at input 28 takes place during a flank at sampling point 22, 24, or 26.

Flip-flops 30, 32, and 34 then require a specific time until a stable end state is reached. This time is ensured in the present example in that the value of flip-flops 30, 32, and 34, which has become stable in the meantime, is only accepted in flip-flops 40, 42, and 44 during the following active flank of the signal at input 28. Flip-flops 30, 32, 34, 40, 42, and 44 are used as storage elements.

Fundamentally, ring oscillator 10 may therefore be constructed from nine inverters 18, for example. One of these inverters 18 may be replaced by NAND element 14, to be able to stop ring oscillator 10. Alternatively, this NAND element 14 may also be replaced by a NOR element.

The values of ring oscillator 10 are stored in the embodiment shown at three different inverters at the same time in one flip-flop (FF) 30, 32, 34 in each case. These taps are to be distributed as equally as possible over the elements of ring oscillator 10. Therefore, for the case of nine inverting stages in ring oscillator 10, a tap or a sampling point 22, 24, 26 is provided after each three inverting elements. As already mentioned, however, this is not required for the provided method. It is also possible to provide a tap again after an even number of inverting elements.

The number of the inverter stages in ring oscillator 10 determines the frequency of the oscillator and should therefore be selected so that the flip-flops may store the particular signal value. If the highest possible oscillator frequency is used, the probability of being in the vicinity of a flank during the sampling is higher. Therefore, the lowest possible number of inverters is selected in the oscillator ring, but sufficiently many are selected that the flip-flops are able to work at the achieved frequency. For a 180 nm technology, a frequency of approximately 1 GHz would be determined for ring oscillator 102 having nine inverters 18 in a simulation. The flip-flops may store the signal values at this frequency, as was shown.

The provided method may be carried out using ring oscillator 10 according to FIG. 1, which has an odd number of inverting elements, values being tapped at at least one sampling point of ring oscillator 10.

A correlation to the system clock and therefore to the sampling clock obtained therefrom may be established for ring oscillator 10. For this purpose, one compares whether the three bit values at the output of flip-flops 30, 32, and 34 are identical to those at the output of flip-flops 40, 42, and 44. Not all correlations may be established by the comparison of s10, s11, s12 with s10′, s11′, s12′, even if the divisor value of the frequency divider is divisible by the number of the inverting elements in the oscillator ring. Sampling may always be carried out at the same position in the oscillator cycle in each case after an arbitrary, possibly constant number of samples. If this number is not simultaneously a divisor of the number of inverting elements in the oscillator, no indication of the existing correlation is obtained by the above-described comparison. It is then nonetheless possible to establish the correlation if all samples are compared to the current sample. However, this is very complex.

For the ring oscillator according to FIG. 1 having, for example, nine inverters and three sampling points, the bit values stored at the sampling points generally change at least one bit value after a number of samples which is not excessively high. A high number of successive equal bit values is recognized by the counting of warnings and either an error is signaled or influence is taken on the frequency of the oscillator.

For the ring oscillator according to FIG. 1, therefore nine inverters and three sampling points are provided. In a first flip-flop, which is connected in each case to a sampling point of the oscillator, the states of the oscillator are stored at the sampling point. The second series of successive flip-flops is suitable for the purpose of compensating for metastable states in the first flip-flops in each case. Such metastable states may arise because the sampling clock is active precisely during a state transition of the oscillator. It is ensured by the renewed storage of the state in the particular second flip-flop that the state of the first flip-flop may settle over one period of the sampling clock, before this stable value is accepted in the second flip-flop. If this structure is implemented in balanced form, a desired behavior may be achieved. However, the balancing requires special gates, namely inverters and flip-flops, to be used, which have a sufficiently equal driver strength for the low-high and the high-low flanks, also for the internal nodes of the flip-flops. In addition, the layout must be constructed so that equal load capacitances are provided for all taps of the ring oscillator and their activating nodes. For example, bit assignments 000 and 111 do not occur in a balanced circuit according to FIG. 1.

In a present test chip, gates of a digital standard library are used. The ring oscillator may additionally also have a tap, to which an amplifier is connected for the purposes of frequency measurement. During measurements on this test chip, it was able to be established that the predicted distribution of the output bits did not apply. Both the values 000 and 111 occurred. In addition, it was established that the distribution of the remaining six states was not uniformly distributed, even if the sampling frequencies were varied. In particular, it was established that in the observed test chip, the number of the samples having the decimal values of the three sampled bits 3, 5, and 6 is significantly higher than that of 1, 2, and 4.

It has been recognized that when post-processing is carried out, during which the three output bits are XOR-linked to one another, 0 occurs much more frequently than 1 as a result. Such skewing of the 0-1 distribution (bias) should actually be avoided or at least corrected by suitable post-processing. The obtained sequence of random bits is also referred to as an internal random sequence, which should have an equal distribution of 0 and 1, see: Killmann, W., Schindler, W.: AIS 31, version 1, BSI of 25 September 2001. If such a distribution of the internal random sequences is not possible, a complex structure is also permitted as post-processing, which generates the random numbers from the internal random sequences. Since distortion is possibly carried out by such structures, which only conceals the true, namely inadequate behavior, a special testing ability is also required after the post-processing if the test of the internal random sequences was not successful. This certification mode required for this purpose is described, for example, in the document DE 60 2004 011 081 T2. If such a test is passed, the post-processing structure may therefore be considered to be suitable and the tests with regard to the equal distribution of 0 and 1 may also be shown on the output data of this complex post-processing structure.

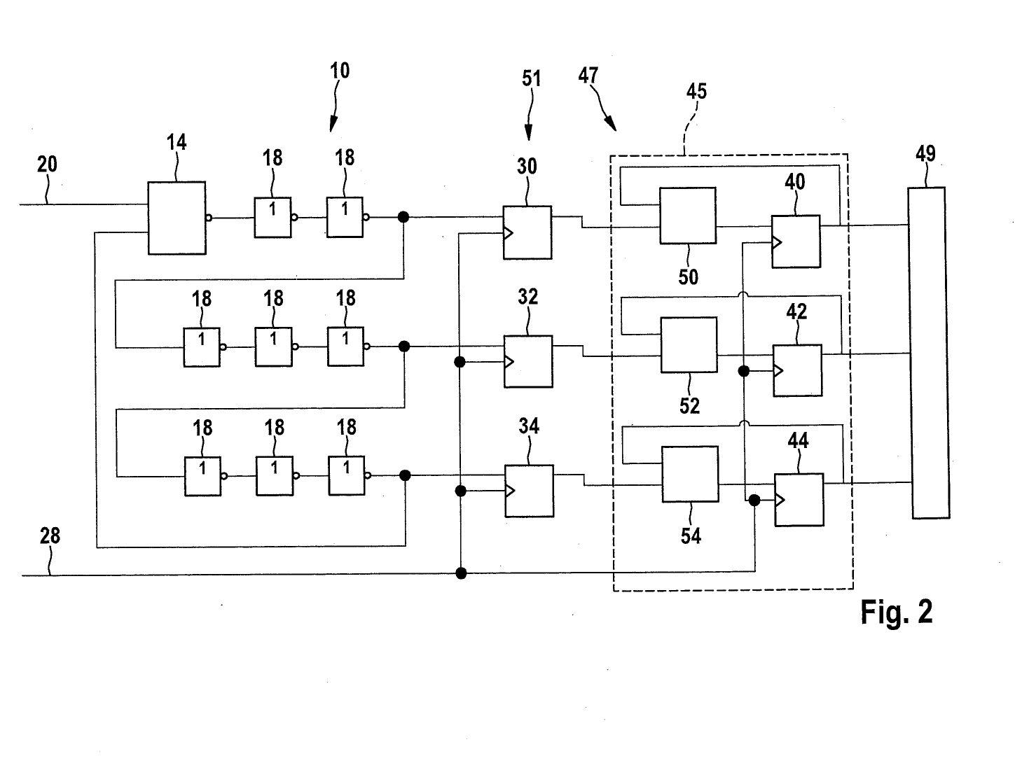

Using the described method, such a structure and in particular the certification mode are saved. This is possible if the compression is carried out in such a way that the internal states of the post-processing circuit are reset after each output of a random bit. For this purpose, for example, a simple compression is already carried out bit-by-bit before the individual bits are further processed. In the circuit of FIG. 2, a compression using a serial XOR in each case is provided, before the value is stored in the second flip-flop. Storage elements 40, 42, and 44 of FIG. 2 are reset after each output to output unit 49. The “stateless” compression thus achieved saves an additional certification mode.

FIG. 2 shows a configuration 47 having ring oscillator 10 from FIG. 1, a first XOR element 50, a second XOR element 52, and a third XOR element 54 being provided. A bit-by-bit compression is carried out using these elements. The compressed values are available in second flip-flops 40, 42, and 44 after completion of the compression. Their outputs are identified with s10″, s11″, and s12″ (s1i″). These values are stored in output unit 49 and may also be checked therein with regard to their distribution. XOR elements 50, 52, and 54, together with flip-flops 40, 42, 44, represent a processing unit 45 for compression. Flip-flops 30, 32, and 34 are used as storage elements, whose outputs s10, s11, and s12 are post-processed and represent a sampling unit 51.

After the sampled values of ring oscillator 10 are stored in each one of first flip-flops 30, 32, and 34, each individual bit s1i is XOR-linked in a second step to the output of one of second flip-flops 40, 42, or 44. A compression is thus achieved, for example, by incorporating the value of s1i in the value of s1i″ n times.

Second flip-flop 40, 42, 44 also fulfills the object at the same time that metastable states in first flip-flop 30, 32, or 34 are taken into consideration, in that one whole sampling period is available for the settling of this labile state. Degree of compression n should be selected to be sufficiently large that the prescribed 0-1 distribution is achieved for each individual bit. As a result, the three random bits may be combined to form one single random bit. For this purpose, the three bits may be linked to one another in an antivalent way, i.e., with the aid of XOR, or may also be incorporated in parallel in a post-processing structure. This post-processing structure may also be a PRNG, which generates pseudo random numeric sequences from the random numbers. If the original random number (typically referred to as a seed) is not known, the output of the PRNG is also not predictable. It is advantageous if compression factor n is odd as much as possible. Thus, n successive zeros result in a different bit value (0) than n successive ones (1). Furthermore, it could be advantageous if n is a prime number, because the compression cannot then be composed of a sum of multiple compressions.

The bit-by-bit serial XOR-linkage fulfills the purpose of remedying an odd number of 0-1 distributions, on the one hand, and enriches the entropy (the random value) by the compression, on the other hand.

The improved distribution of 0 and 1 is determined by the level of compression factor n. Better uniform distribution generally results with greater n.

It is also to be considered at the same time how much entropy the sampled values contain. It plays a role how much jitter is present at the point in time of the sampling. The jitter may be calculated using

$${σ}_{Δ T} = \sqrt{\frac{8}{3 η}} \sqrt{\frac{{V}_{DD}}{{V}_{Char}} \frac{{k}_{B} T}{P}} \sqrt{Δ T} . \qquad ( 1 )$$

For short channel transistors:

$${V}_{Char} = \frac{3}{8} ( \frac{{V}_{DD}}{2} - {V}_{T} ) \qquad ( {2}^{′} )$$

and furthermore

k_{B}: Boltzmann constant (1.38*10⁻²³ J/K)

η: technology constant of the switch elements used (typically ≈1)

V_{DD}: operating voltage of the oscillator (for example, 1.8 V)

T: temperature (for example, 298 K)

P: power consumption of the oscillator

V_{T}: threshold voltage of the transistors in the oscillator

ΔT: time span between two samples σ_{ΔT}: standard deviation of the jitter

To calculate the entropy, it is presumed that in a range of ±1.299 σ_{ΔT} around an oscillator flank, the entropy value is 0.5 and the value 0 is assumed outside this range. If it is now assumed that the samples are distributed uniformly over the oscillator period, if the oscillator frequency and the sampling frequency do not oscillate with one another, an entropy value is thus obtained in accordance with the proportion of the range of ±1.299 σ_{ΔT} and the corresponding number of the flanks to be taken into consideration in relation to the oscillator period. This entropy value will assume the √2=1.414-fold value in the event of doubling of the sampling period, because the jitter increases to the 1.414-fold value according to the above equation. In the same period of time, however, one has only one sampled value, while one had two sampled values before the doubling of the sampling period.

If the entropy is equal to x in the case of single sampling periods, it will thus be 2*x in the case of two samples. However, in the case of the doubling of the sampling period, one only obtains a value of 1.414*x for the entropy in the same period of time.

It is therefore more advantageous to not select the sampling periods to be excessively long and to compress more sampled values for this purpose, i.e., to have the highest possible n. On the other hand, it may also be disadvantageous to compress excessively many sampled values using the serial XOR according to FIG. 2, because then entropy values may mutually compensate for one another. It is to be noted that an even number of entropy values “1” mutually cancel out during the XOR compression. Experimental studies have shown that a compromise for the sampled values with n may be between several tens and several hundreds up to a few thousand. The sampling frequencies were in this case between 300 kHz and 12.5 MHz at an oscillator frequency of approximately 1 GHz. The internal random sequences thus obtained already passed the generally recognized typical statistical tests, without using additional post-processing.

It may therefore be claimed that a ring oscillator is constructed from digital standard elements, specifically inverters or inverting elements and a NAND or NOR for stopping the oscillator. Furthermore, it may be claimed that the digital standard design flow may be used for the design of the ring oscillator and the sampling flip-flop, because no manual intervention in the layout is necessary. In the present test chip, both the digital elements were distributed very asymmetrically in their driver effect with respect to the flanks and also the capacitive load of the ring oscillator was distributed very differently by the connection of an amplifier for the frequency measurement. All of this no longer had a disadvantageous influence on the statistical tests after the XOR compression with suitable parameters. The conditions of the tests may therefore be fulfilled without additional complex structures for post-processing. For this purpose, the three compressed signals may be linked to one another by an XOR (anti-valence) function or another linear function, for example, equivalents, and this output signal may be further processed.

In another embodiment, the output bits of the three sampling flip-flops may also be linearly linked to one another before the XOR compression, for example, by XORs (anti-valence) or also equivalence operators (XNOR).

Furthermore, a unit 49 is provided for outputting and checking the compressed signal values with regard to their distribution. The above-mentioned XOR-linkage of the three compressed bits may also be carried out in this unit 49, for example, one output bit of the random generator being generated in each case.

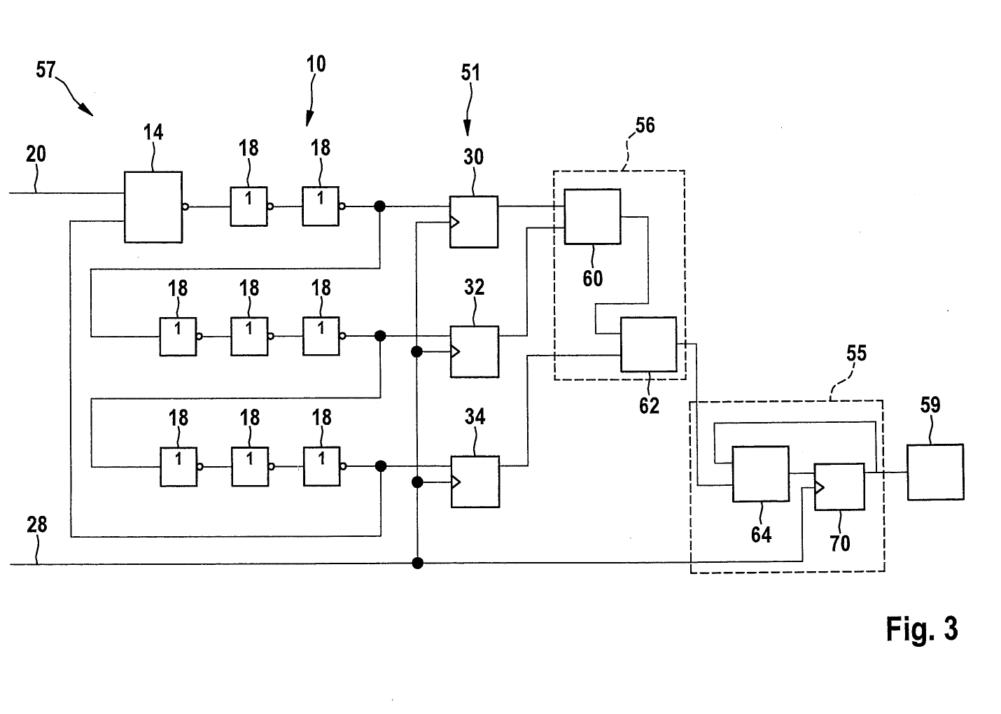

FIG. 3 shows a random generator 57 as a possible embodiment of the provided system having ring oscillator 10 and having a first XOR element 60 having output s01, a second XOR element 62 having output s012, and a third XOR element 64. Furthermore, a second flip-flop 70 is provided, which outputs s012″. XOR elements 60, 62 form a linkage unit 56 for linking the three output signals to form a combined, non-compressed output signal. XOR element 64 and flip-flop 70 form a processing unit 55 for the compression. The number of bits nᵢ, which come out of XOR element 62 and are processed to form a random bit, corresponds to compression factor nᵢ. Furthermore, a unit 59 is shown for checking a distribution for the storage and output of the stored random bits.

The advantage of this embodiment is that only one signal must still be serially compressed with the aid of XOR. However, it is to be noted that the properties of the circuit may no longer be judged as well as if the three compressed signals were provided. Because of the linearity of the XOR operations, the output signals of FIG. 2 and FIG. 3 are identical when the three output signals of FIG. 2, s10″, s11″, and s12″ are linked using XOR to form a signal s012″:

s012″=s10″⊕s11″⊕s12″

where

s10″=s10(0) ⊕s10(1)⊕s10(2) . . . ⊕s10(n−1)

s11″=s11(0) ⊕s11(1)⊕s11(2) . . . ⊕s11(n−1)

s12″=s12(0) ⊕s12(1)⊕s12(2) . . . ⊕s12(n−1)

the above equation becomes

s012″=s10(0)⊕s10(1) . . . ⊕s10(n−1)⊕s11(0)⊕s11(1) . . . ⊕s11(n−1)⊕s12(0)⊕s12(1) . . . s12(n−1).

and according to FIG. 3:

s012 =s10⊕s11⊕s12

and

012″=s012(0)⊕s012(1)⊕s012(2) . . . ⊕s012(n−1)

the above equation becomes

s012″=s10(0)⊕s11(0)⊕s12(0)⊕s10(1)⊕s11(1)⊕s12(1) . . . ⊕s10(n−1)⊕s11(n−1)⊕s12(n−1).

Because of the commutative law of anti-valence, according to which it is possible to exchange the operands as desired, both equations for s012″ are identical.

A TRNG is implementable using the provided method as IP (intellectual property). IP refers to a product which provides a circuit description together with tests in such a way that a customer of this product is capable of implementing the circuit on a chip using his own technology. Because of the extremely low circuitry outlay, specifically approximately 200 gate equivalents, it is usable practically anywhere randomness plays a role.

The present invention may additionally be used in sensor analysis units for manipulation protection or in security applications in the case of connections to the Internet of such TRNGs.

Furthermore, a circuit configuration having at least one ring oscillator is provided, which includes a ring-shaped interconnection of an odd number of inverting elements, this ring oscillator being sampled at one or more sampling points or positions, the sampled values being stored simultaneously in storage elements using a sampling clock, the outputs of the storage elements being connected to an input of a linear linkage element.

In addition, a circuit configuration having a random source is provided, having at least one digital output signal having a bit width of at least one bit and a circuit for compressing this output signal, the circuit carrying out a block-by-block XOR-linkage of n bits of each bit of the output signal to form one bit in each case of a compressed output signal and the sequence thus formed of the compressed signal values being checked with regard to their distribution. The block-by-block XOR-linkage means that n successive bits are each XOR-linked to one another serially. The checking of the distribution may be carried out for each individual output bit according to FIG. 2 or for the combined output bit according to FIG. 3, for example, so that the number of the zeros and ones in this bit sequence is counted and these count values are compared to one another. This comparison may be carried out, for example, by calculating the difference of the two count values, it being checked whether the difference exceeds a predefined maximum value. A comparison to fixed barriers may also be carried out.

The circuit configuration may be distinguished in that influence is taken on compression factor n as a function of the result of the check of the distribution.

Furthermore, the random source may contain at least one ring oscillator, which is made of a ring-shaped interconnection of an odd number of inverting elements, this ring oscillator being sampled at at least one position using a clock.

Influence is taken on the frequency of the sampling clock as a function of the result of the check.

Furthermore, as a function of the result of the check of the distribution, influence may be taken on the frequency of the ring oscillator, for example, by way of the number of inverting elements in the ring oscillator or by changing the operating conditions of the oscillator (operating voltage, temperature).

The output signal of the random source may include multiple bits and at least two of these bits may be combined by a linear linkage to form one bit, which is accordingly compressed by block-by-block XOR-linkage of n bits and the compressed bit sequence is checked with regard to its distribution.

The output signal of the random source may include at least k bits, which are not linked to one another, and each of these k bits is provided with a circuit for processing the output signal, which, corresponding to compressed k bits, form an assignment with 2^{k} possible values and the occurrence of all of these 2^{k} possible values are counted in separate counters and the frequency of all of these assignments are mutually compared.

A check of the distribution may be carried out, for example, by counting the occurrence of bit value 0 and bit value 1 in separate counters for m compressed output bits and carrying out the comparison by calculating the difference of these counter values and comparing the difference as to whether it exceeds a predefined barrier.

In the embodiments of FIGS. 1 through 3, a simple compression with the aid of XOR is provided, degree of compression n being selected to be sufficiently large that the prescribed 0-1 distribution is achieved for each individual bit, as is inferred from FIG. 2. After an XOR-linkage of the compressed 3 bits, 1 bit of random value having a uniform 0-1 distribution and maximum entropy is obtained. More entropy is typically contained in the uncompressed 3 bits than may be represented in the one compressed bit. Entropy is therefore destroyed. As shown in FIG. 3, the three oscillator sampled bits, the so-called raw data, may also already be XOR-linked to one another before the compression is carried out using a single XOR.

In contrast, in the case of the single compression of the 3 bits, one has the advantage that the properties of the resulting bits may be judged better.

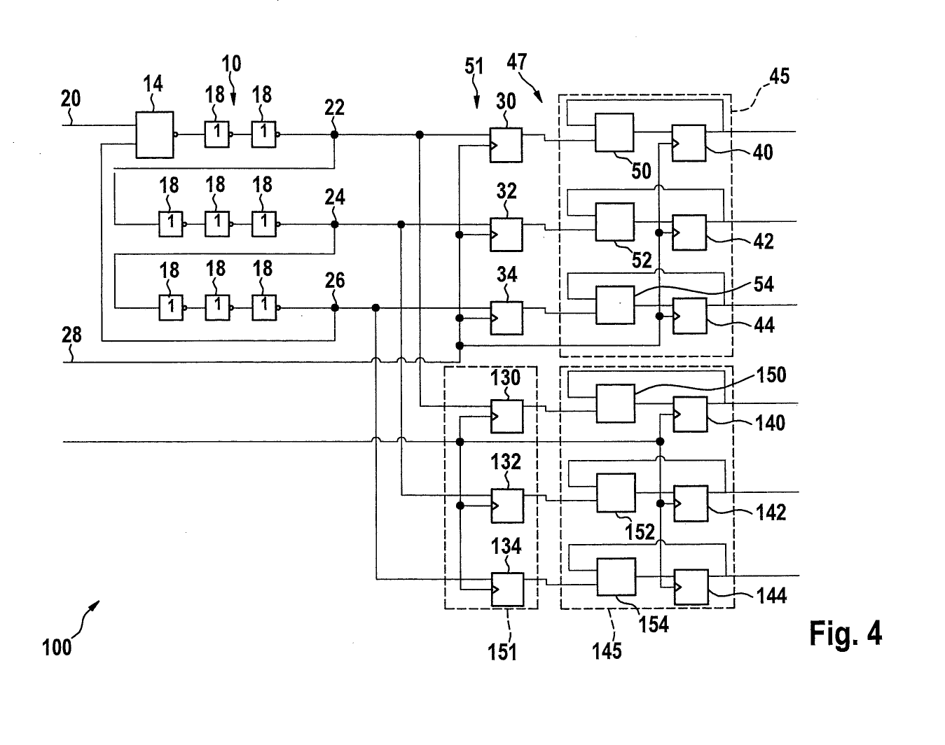

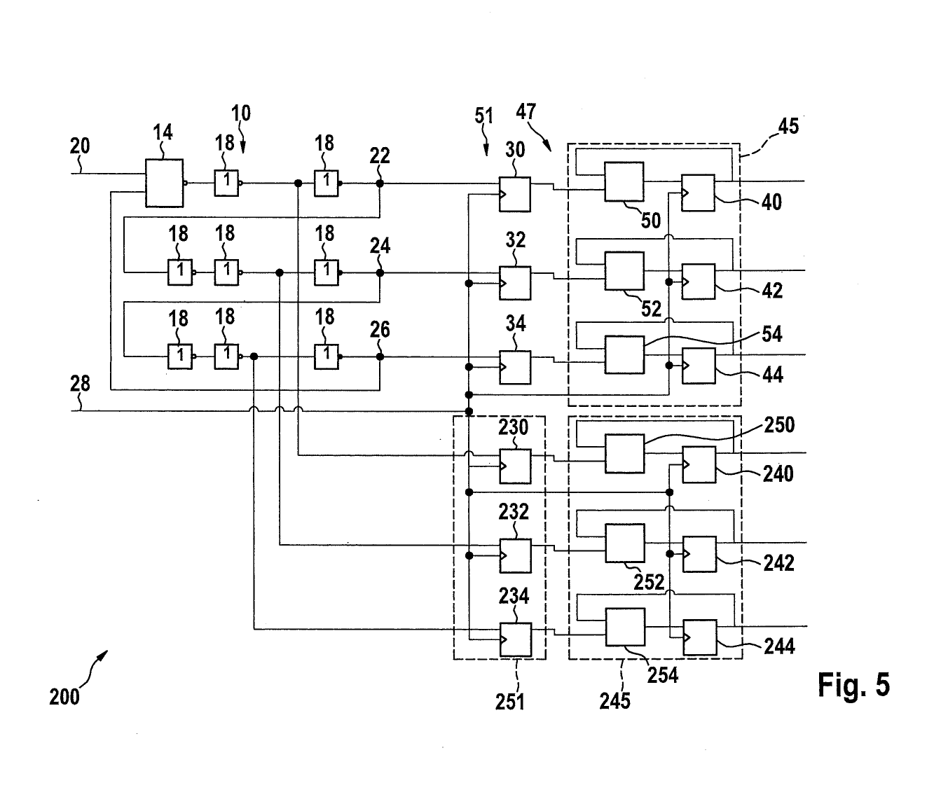

FIGS. 4 and 5 show configurations which permit multiple sampling of oscillator 10.

FIG. 4 shows a configuration for carrying out the provided method, which is identified as a whole with reference numeral 100 and interacts with ring oscillator 10 from FIG. 1. Configuration 100 builds on configuration 47 from FIG. 2. A second sampling unit 151 is additionally provided having first flip-flops 130, 132, and 134, and a second processing unit 145 having XOR elements 150, 152, and 154 and second flip-flops 140, 142, and 144. First processing unit 45 and second processing unit 145 operate in parallel with one another, in such a way that two compressed output signals are generated, which have a bit width of at least one bit.

In configuration 100 in FIG. 4, the same sampling points 22, 24, and 26 of ring oscillator 10 are used by both processing units 45 and 145 and first flip-flops 30, 32, 34 or 130, 132, 134, which are also referred to as sampling flip-flops, are controlled using different clocks. The downstream XOR compression circuits may have identical or different compression factors. The compression may also be implemented more simply, as embodied in FIG. 3. Compressed bits s10″, s11″, and s12″ may be checked for the 1-0 distribution and subsequently combined to form an output bit by XOR-linkage.

The same procedure is used with bits s20″, s21″, and s22″. These output bits are either used directly as random bits or further processed, separately or together. Even if a single compression of the three sampled bits takes place according to FIG. 3, the 0-1 distribution may be checked. If different sampling frequencies and/or different compression factors are used, the distribution must be checked separately for each compression unit. Equal sampling frequency and equal compression are only advisable for the variant of FIG. 5, or if two sampling clocks having equal frequency, but phase-shifted in relation to one another, are used for the circuit of FIG. 4.

FIG. 5 shows a configuration for carrying out the provided method, which is identified as a whole with reference numeral 200 and interacts with ring oscillator 10 from FIG. 1. Configuration 200 builds on compression configuration 47 from FIG. 2. In addition to first processing unit 45, a second processing unit 245 is provided, having first flip-flops 230, 232, and 234, XOR elements 250, 252, and 254, and second flip-flops 240, 242, and 244.

If the two sampling frequencies are equal and the sampling is either carried out at different sampling points or the frequencies are phase-shifted in relation to one another, only the output signals of one compression unit need to be checked with regard to the distribution. The unit having the lower compression factor must be checked; as experimental studies have shown, the randomness of the data is also provided in the case of a higher compression factor if correspondingly high requirements are placed on the testing criteria.

The checking of the distribution is carried out by counting the assignments of the particular output bits of a compression unit in the case of a fixed number of samples and comparing to fixed values or to one another by calculating the difference.

If the differences are excessively high or they exceed or fall below the predefined limits, the data thus should not be used. An improvement of the data quality may be achieved by a change of the sampling frequency and/or the compression factor.

The sampling using different sampling frequencies has a further advantage if the two sampling clocks are independent of one another. In this case, a correlation between the oscillator contact and the two sampling clocks is not possible. If a correlation only occurs at one sampling clock, the circuit having the other sampling clock thus always still provides an equal distribution of the samples over the oscillator period. This is a necessary basic requirement to achieve a sufficiently high degree of randomness, measured by the entropy. However, there may also not be a sufficient amount of randomness in the two processing units if the jitter disappears or is at least very small due to coupling of the oscillator to a system clock.

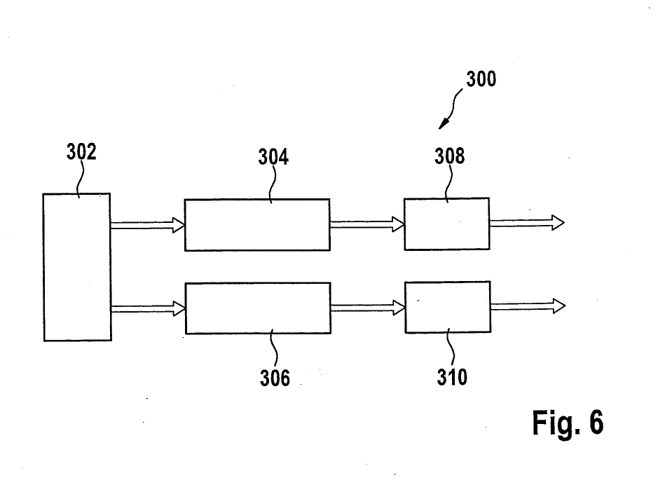

FIG. 6 shows the general structure of a circuit configuration 300. Reference numeral 302 identifies the random source; reference numerals 304 and 306 identify sampling units. Processing units are identified by reference numerals 308 and 310. Processing units 308 and 310 may carry out a compression or other processing.

It is to be noted that in the case of the provided circuit configuration, the required circuit outlay is very low and digital standard methods may be used. Because of the extremely low circuitry outlay, approximately 200 gate equivalents, it is usable nearly everywhere randomness plays a role, for example, Car2x, smart phone IPs for secure applications, online banking, communication of confidential data, key generation, side channel robustness, etc.

With reference to FIG. 6, a circuit configuration having at least one random source and at least two sampling units is provided, which are connected to this one random source and in which random values are stored, the two sampling units each being connected to different compression configurations or processing units and these processing units each providing different output signals and at least one of these output signals being checked for properties.

A ring oscillator may be used as a random source. The two sampling units then tap the ring oscillator at identical or different sampling points.

Furthermore, the two sampling units may each sample the random values at the random source using one clock of the same frequency in each case, a phase shift being able to exist between these two clocks. In addition, the two sampling units may each sample the random values at the random source using one clock of different frequency.

The processing units may carry out a compression using equal or different compression factors. In addition, the at least one output signal may be checked in that the frequency of the possible assignments of the output signal is counted and compared to predefined limits.

What is claimed is:

1. A method for generating an output of a random source of a random generator, which outputs at least two output signals each having a bit width of at least one bit, the method comprising:
sampling the random source using at least two sampling units to generate two output signals; and
processing the respective output signal of each sampling unit by a respective processing unit.

2. The method as recited in claim 1, wherein a compression is carried out in each processing unit, and wherein in the compression, a block-by-block linear linkage of n successive bits of the output signal is carried out, n being a compression factor, whereby a compressed output signal is generated in each case, which includes a sequence of compressed signal values.

3. The method as recited in claim 2, wherein each sampling unit samples at sampling points which differ from sampling points of the other sampling units.

4. The method as recited in claim 2, wherein the sampling units sample at identical sampling points using different sampling clocks.

5. The method as recited in claim 3, wherein the sequence of the compressed signal values of at least one processing unit is checked with regard to distribution of the compressed signal values.

6. The method as recited in claim 3, wherein a ring oscillator, which includes a ring-shaped interconnection of an odd number of inverting elements, is used as the random source, and wherein the ring oscillator is sampled at at least one sampling point using a sampling clock.

7. A configuration for generating an output of a random source of a random generator, which outputs at least two compressed output signals having a bit width of at least one bit, comprising:
at least two sampling units each configured to sample the random source so that an output signal is generated in each case; and
at least two processing units configured to process the output signals of the at least two sampling units.

8. The configuration as recited in claim 7, wherein a compression is carried out in each processing unit, and wherein in the compression, a block-by-block linear linkage of n successive bits of the output signal is carried out, n being a compression factor, whereby a compressed output signal is generated in each case which includes a sequence of compressed signal values.

9. The configuration as recited in claim 8, further comprising a unit configured to check the sequence of the compressed signal values with regard to distribution of the compressed signal values.

10. The configuration as recited in claim 8, wherein a ring oscillator is used as the random source.

11. The configuration as recited in claim 8, wherein the sampling units are configured to sample at identical sampling points.

12. The configuration as recited in claim 8, wherein the sampling units are configured to sample at different sampling points.
